(19) United States
(12) Patent Application Publication
(10) Pub. No.: US 2008/0032212 A1
(43) Pub. Date: Feb. 7, 2008

(54) High Definition Mask and Manufacturing Method of the Same

(76) Inventor: Jae HYUN KANG, Suwon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/833,768

(22) Filed: Aug. 3, 2007

(30) Foreign Application Priority Data
Aug. 3, 2006 (KR) 10-2006-0073477

(51) Int. Cl. G03F 1/00

(52) U.S. Cl. 430/5

(57) ABSTRACT

A high definition mask and a manufacturing method of the same are provided. The high definition mask according to an embodiment includes a quartz plate; a phase shift mask (PSM) area found on the quartz plate in a predetermined pattern; and a chromeless mask (CLM) are formed in a finger pattern as compared to the PSM area.

### CROSS-REFERENCE TO RELATED APPLICATION

The present application claims the benefit under 35 U.S.C. §119 of Korean Patent Application No. 10-2006-0073477, filed Aug. 3, 2006, which is hereby incorporated by reference in its entirety.

### BACKGROUND

In general, an attenuated phase shift mask (APSM) uses a shifter to selectively transmit light of about 6 to 15% when chrome perfectly interrupts light.

However, it is difficult to implement a fine pattern using only the APSM due to its resolution in an exposure of patterns of 70 nm or less. This can be appreciated through FIGS. 1 and 2.

FIG. 1 shows an APSM according to the related art and FIG. 2 is a graph showing intensity of light transmitted using the APSM shown in FIG. 1.

Referring to FIGS. 1 and 2, the APSM in the related art has a shifter 20 patterned on a quartz plate 10. The shifter 20 is formed of an area 21 implementing a 100 nm pattern and an area 22 implementing a 70 nm pattern.

When implementing the pattern using the shifter 20, FIG. 2 indicates that there is not any problem in the intensity of light for implementing the 100 nm pattern, but there is a problem in the intensity of light for implementing the 70 nm pattern. Therefore, since the intensity of light when implementing 70 nm pattern is degraded, the light is not completely transmitted to the bottom so that a value gap 30 occurs.

In order to solve the problem, a double exposure lithography (DEL) involving two exposures using two masks has been introduced. However, this also causes an alignment problem during a photo process so that DEL can be difficult to implement.

### BRIEF SUMMARY

Embodiments of the present invention provide a high definition mask and method of manufacturing thereof.

A high definition mask according to an embodiment of the present invention comprises: a quartz plate; a PSM (phase shift mask) area formed on the quartz plate in a predetermined pattern; and a CLM (chromeless mask) area formed in a finer pattern as compared to the PSM area.

A manufacturing method of a high definition mask according to an embodiment of the present invention comprises: providing a quartz plate; forming PSM patterns and CLM patterns in a PSM area and a CLM area, respectively, of the quartz plate; forming the CLM area by etching the quartz plate using the CLM patterns as a mask; and removing the CLM patterns.

### BRIEF DESCRIPTION OF THE DRAWINGS

FTG. 1 is a view showing an APSM (attenuated phase shift mask) in the related art.

FIG. 2 is a graph showing intensity of light transmitted using the APSM shown in FIG. 1.

FIG. 3 is a view showing a high definition mask according to an embodiment of the present invention.

FIG. 4 is a graph showing intensity of light transmitted using the high definition mask shown in FIG. 3.

FIG. 5 is a view showing a shifter formed on a quartz plate prior to being patterned according to an embodiment of the present invention.

FIG. 6 is a view showing that the shifter shown in FIG. 5 is patterned.

FIG. 7 is a view showing that a resist pattern is formed by applying a resist to the shifter shown in FIG. 6 and patterning it.

FIG. 8 is a view of a high definition mask completed according to the embodiment.

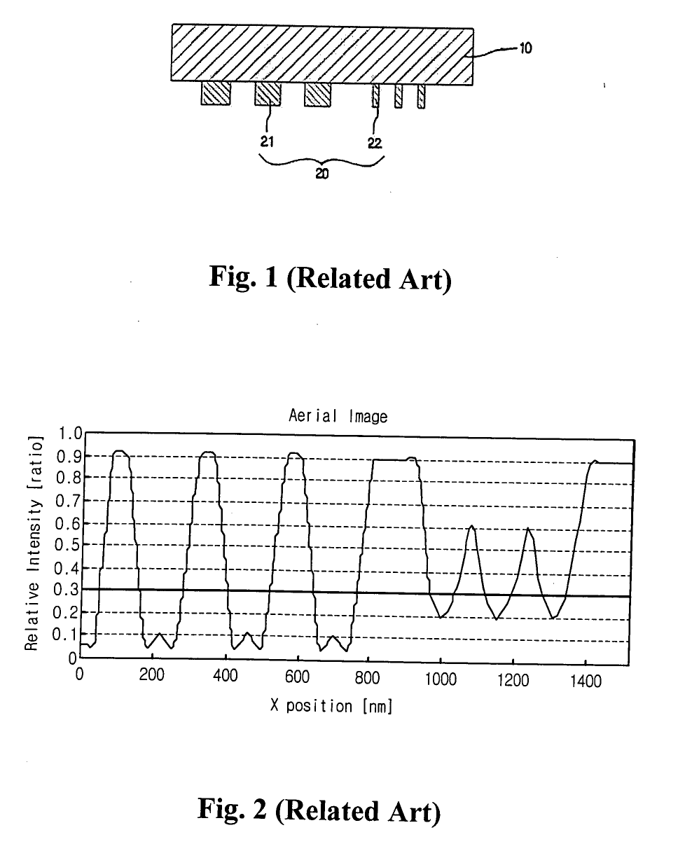

DETAILED DESCRIPTION

Hereinafter, embodiments of the present invention will be described with reference to the accompanying drawings. However, they are not limited to the embodiments set forth herein.

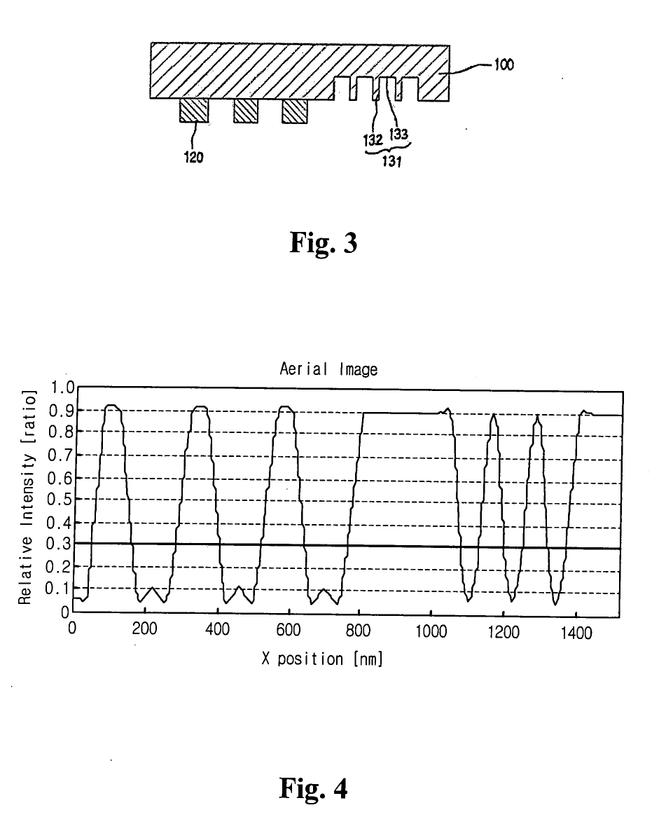

FIG. 3 is a view showing a high definition mask according to an embodiment, and FIG. 4 is a graph showing intensity of light transmitted using the high definition mask shown in FIG. 3.

Referring to FIG. 3, a high definition mask is provided with a phase shift mask (PSM) area 120 and a chromeless mask (CLM) area 131 formed on a quartz plate 100.

The PSM area 120 is an area capable of implementing a pattern sized about 100 nm, and the CLM area 131 is an area capable of implementing a pattern sized about 70 nm.

The CLM area 131 can be formed as a pattern in a portion of the quartz plate 100. A predetermined height difference is formed between a first area 132 and a second area 133 of the CLM area 131.

Through the height difference, a difference is generated in the respective light waveforms transmitting from the first area 132 and the second area 133 similar to a phase shift effect. Because of this difference of the respective light waveforms, interference and cancellation between such waveforms are generated.

By providing the predetermined height difference and generating the interference and the cancellation between the light waveforms, it is appreciated that the intensity of light for the 70 nm pattern can be provided in an intensity to the extent almost corresponding to the intensity of light for the 100 nm pattern, as shown in the graph of FIG. 4.

In other words, because of the interference and the cancellation between lights due to the difference of the respective light waveforms transmitting from the first area 132 and the second area 133 of the CLM area 131, the intensity can reach the extent required for the intensity of the transmitted light for forming the 70 nm pattern as well as the 100 nm pattern. Therefore, since the light can be transmitted up to the required depth, the definition of the mask can be improved.

According to embodiments as described above a PSM area 120 and a CLM area 131 are formed so that the definition of the mask can be improved, and required patterns of various sizes and definition can simultaneously be implemented even by means of one exposure.

In other words, when using a mask according to an embodiment of the present invention, the CLM area 131 for implementing a fine pattern can be simultaneously exposed in the process of exposing the PSM area 120 for implementing a layer pattern, without adding a second exposure for the CLM area 131. Therefore, the manufacturing process thereof is simple, making it possible to reduce the costs and the time rendered in the manufacturing process.

Herein, the height difference between the first area 132 and the second area 133 of the CLM area 131 can be formed to be the same as the half waveform of the light.

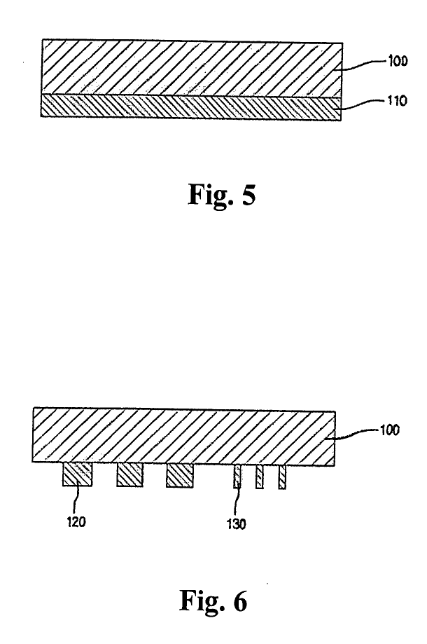

FIGS. 5 to 8 are views for explaining a manufacturing method of a high definition mask according to an embodiment.

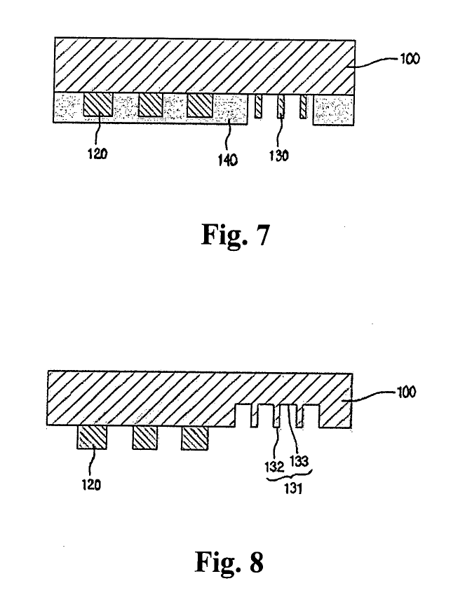

FIG. 5 is a view showing a shifter formed on a quartz plate prior to being patterned according to an embodiment, FIG. 6 is a view showing that the shifter of FIG. 5 is patterned, FIG. 7 is a view showing that a resist pattern is formed by applying and patterning a resist to the shifter of FIG. 6, and FIG. 8 is a view of a high definition mask completed according to an embodiment.

Referring to FIG. 5, a shifter material 110 can be formed on a quartz plate 100.

Thereafter, referring to FIG. 6, the shifter material 110 formed on the quartz plate 100 can be patterned. By patterning the shifter 110, a PSM pattern 120 can be formed in the PSM area of the shifter 110 and a CLM pattern 130 can be formed in the CLM area thereof.

As described above by means of the collective patterning on the shifter 110, both the PSM pattern 120 and the CLM pattern 130 can be formed on the shifter 110. Therefore, an additional process of forming the CLM pattern 130 in the shifter 110 is not required so that the manufacturing process can be simplified.

Referring to FIG. 7, a resist 140 can be applied to the quartz plate 100 provided with the PSM pattern 120 and the CLM pattern 130 in the shifter 110. After such an application is made, the resist 140 is exposed and patterned to form a resist pattern from the resist 140.

At this time the resist in the CLM area is removed so that the CLM pattern 130 is exposed.

Herein, although the CLM pattern 130 is exposed, the resist 140 on the PSM pattern 120 remains so that the PSM pattern 120 is not exposed.

Then, referring to FTG. 8, an etching process can be performed on the quartz plate 100 by using the CLM pattern 130 made of the shifter material as an etch mask. According to an embodiment, the etching is progressed to a depth of a half wavelength of the wavelength for the light to be transmitted.

As described above, the quartz plate 100 in the lower portion thereof is etched in a predetermined pattern by means of the CLM pattern 130.

Meanwhile, the resist 140 remains on the PSM pattern 120 so that the PSM pattern 120 is in a state not exposed to the external. Therefore, although the etching is progressed in the CLM area, the etching is not progressed in the PSM pattern area. The etching can be performed only at the quartz plate 100 using the CLM pattern 130 exposed to the external.

The resist 140 on the PSM pattern 120 is removed, resulting in the PSM pattern 120 on the quartz plate 100 and a CLM area 131 in the quartz plate 100 formed of the first area 132 and the second area 133 formed in a shape recessed by a predetermined depth from the first area 132 to have a predetermined height difference from the first area 132.

Through Such a manufacturing process, both the PSM pattern 120 and the CLM area 131 can be formed on the quartz plate 100.

According to embodiments of a high definition mask and a manufacturing method of the same, both the PSM area and the CLM area are formed so that the definition of the mask is improved as well as the required various patterns of definition can simultaneously be implemented by means of one exposure, having an effect that the costs and the time rendered in the process can be reduced.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments therefore, it should be understood that numerous other modifications and embodiments can be devised by those skilled in the art that will fall within the spirit and scope of the principles of this disclosure. More particularly, various variations and modifications are possible in the component part and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A high definition mask comprising:
a quartz plate;
a phase shift mask (PSM) area formed on the quartz plate in a predetermined pattern; and
a chromeless mask (CLM) area formed having a finer pattern compared to the predetermined pattern of the PSM area.

2. The high definition mask according to claim 1, wherein the CLM area comprises an area of the quartz plate etched in a predetermined fine pattern.

3. The high definition mask according to claim 1, wherein the CLM area comprises fine patterns having a predetermined height in the quartz plate.

4. The high definition mask according to claim 3, wherein the predetermined height is equal to half a wavelength of light to be transmitted.

5. A manufacturing method of a high definition mask, comprising:
providing a quartz plate;
forming a phase shift mask (PSM) pattern on a PSM area of the quartz plate;
forming achromeless mask (CLM) pattern on a CLM area of the quartz plate;
etching the quartz plate using the CLM pattern as a mask; and
removing the CLM pattern.

6. The method according to claim 5, wherein forming the PSM pattern and the CLM pattern comprises:
forming a shifter on the quartz plate; and etching the shifter to for, a PSM pattern and a CLM pattern.

7. The method according to claim 5, wherein etching the quartz plate using the CLM pattern as a mask comprises:
forming a resist on the quartz plate including a PSM pattern and a CLM pattern;
removing a portion of the resist to expose the CLM pattern; and mask.

8. The method according to claim 5, wherein etching the quartz plate using the CLM pattern as a mask comprises etching the quartz plate to a depth of a half wavelength of a light to be transmitted.
